(19) United States
(12) Patent Application Publication
(10) Pub. No.: US 2025/0240994 A1
(43) Pub. Date: Jul. 24, 2025

(54) SELECTIVE SILICON NITRIDE WITH TREATMENT FOR BACKSIDE POWER DELIVERY NETWORK

(71) Applicant: Applied Materials, Inc., Santa Clara, CA (US)

(72) Inventors: Kyoung Ha Kim, Cupertino, CA (US); Byeong Chan Lee, San Jose, CA (US); Veeraraghavan S. Basker, Fremont, CA (US); Naomi Yoshida, Sunnyvale, CA (US)

(73) Assignee: Applied Materials, Inc., Santa Clara, CA (US)

(21) Appl. No.: 18/978,098

(22) Filed: Dec. 12, 2024

Related U.S. Application Data
(60) Provisional application No. 63/622,760, filed on Jan. 19, 2024.

(51) Int. Cl. H10D 30/01

(52) U.S. Cl. CPC H10D 30/0191

(57) ABSTRACT

Methods of manufacturing logic or memory devices are provided. The method includes selectively depositing a silicon-containing dielectric layer in a source/drain recess on a substrate and through an opening in an oxide liner within the source drain recess. The silicon-containing dielectric layer is then densified.

### CROSS REFERENCE TO RELATED APPLICATIONS

This application claims priority to U.S. Provisional Application No. 63/622,760, filed Jan. 19, 2024, the entire disclosure of which is hereby incorporated by reference herein.

### TECHNICAL FIELD

Embodiments of the present disclosure pertain to the field of semiconductor devices and semiconductor device manufacturing. More particularly, embodiments of the disclosure relate to methods of reducing backside contact over-etch for both NMOS and PMOS contacts.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

The transistor is a key component of most integrated circuits. Since the drive current, and therefore speed, of a transistor is proportional to the gate width of the transistor, faster transistors generally require larger gate width. Thus, there is a trade-off between transistor size and speed, and “fin” field-effect transistors (FinFETs) have been developed to address the conflicting goals of a transistor having maximum drive current and minimum size. FinFETs are characterized by a fin-shaped channel region that greatly increases the size of the transistor without significantly increasing the footprint of the transistor and are now being applied in many integrated circuits. FinFETs, however, have their own drawbacks.

As the feature sizes of transistor devices continue to shrink to achieve greater circuit density and higher performance, there is a need to improve transistor device structure and to reduce contact resistance. Examples of transistor device structures include a planar structure, a fin field effect transistor (FinFET) structure, and a gate-all-around (GAA) structure. Logic gate performance is related to the characteristics of the materials used as well as the thickness and area of the structural layers. However, as some gate characteristics are adjusted to accommodate device scaling, challenges arise.

As the semiconductor manufacturing industry moves into advanced modes below the 2 nm node, there is a desire to improve speed and drive current of devices through reduction of contact resistance. Accordingly, there is a need for methods of reducing contact resistance.

Connecting semiconductors to a power rail is typically done on the front of the cell (e.g., the semiconductor substrate), which requires significant cell area. Backside power rail formation, connecting backside of source-epi (known as BPR Gen-II) for a logic transistor (e.g., a FinFET or GAA) has been explored for continued area scaling in next generation logic nodes.

Currently known approaches for backside source-epi contact leads to over etching and damage of the device. Accordingly, new methods of manufacturing are needed.

### SUMMARY

One or more embodiments of the disclosure are directed to methods to form a logic or memory device. In one or more embodiments, a method of forming a logic or memory device comprises: selectively depositing a silicon-containing dielectric layer in a source/drain recess on a substrate and through an opening in an oxide liner within the source drain recess; and densifying the silicon-containing dielectric layer.

Additional embodiments of the disclosure are directed to a processing tool. In one or more embodiments, a processing tool comprises: a central transfer station comprising a robot configured to move a wafer; a plurality of process stations, each process station connected to the central transfer station and providing a processing region separated from processing regions of adjacent process stations, the plurality of process stations comprising one or more of a pre-cleaning chamber, an inhibitor soaking chamber, a selective deposition chamber, and a densification chamber; and a controller connected to the central transfer station and the plurality of process stations, the controller configured to activate the robot to move the wafer between process stations, and to cause the processing tool to perform the operations of: selectively deposit a silicon-containing dielectric layer in a source/drain recess on a substrate and through an opening in an oxide liner within the source drain recess; and densify the silicon-containing dielectric layer.

Still further embodiments of the disclosure are directed to methods of forming gate-all-around devices. In one or more embodiments, a method of forming a gate-all-around device comprises: forming an oxide liner on a sidewall surface of a superlattice structure and on a bottom surface of a source/drain recess adjacent to the superlattice structure on a substrate, the superlattice structure comprising a plurality of first layers and a corresponding plurality of second layers alternatingly arranged in a plurality of stacked pairs extending between the source/drain recess; removing a portion of the oxide liner from the bottom surface of the source/drain recess; selectively depositing a silicon-containing dielectric layer in the source/drain recess and through an opening in the oxide liner within the source drain recess; and densifying the silicon-containing dielectric layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a process flow diagram of a method according to one or more embodiments;

FIG. 1B is a process flow diagram of a method according to one or more embodiments;

FIG. 1C is a process flow diagram of a method according to one or more embodiments;

FIG. 1D is a process flow diagram of a method according to one or more embodiments;

FIG. 2 illustrates a cross-section view of a semiconductor device according to one or more embodiments;

FIG. 3 illustrates a cross-section view of a semiconductor device according to one or more embodiments;

FIG. 4 illustrates a cross-section view of a semiconductor device according to one or more embodiments;

FIG. 5 illustrates a cross-section view of a semiconductor device according to one or more embodiments;

FIG. 6 illustrates a cross-section view of a semiconductor device according to one or more embodiments;

FIG. 7 illustrates a cross-section view of a semiconductor device according to one or more embodiments;

FIG. 8 illustrates a cross-section view of a semiconductor device according to one or more embodiments;

FIG. 9 illustrates a cross-section view of a semiconductor device according to one or more embodiments;

FIG. 10 illustrates a cross-section view of a semiconductor device according to one or more embodiments;

FIG. 11 illustrates a cross-section view of a semiconductor device according to one or more embodiments;

FIG. 12 illustrates a cross-section view of a semiconductor device according to one or more embodiments; and

FIG. 13 illustrates a cluster tool according to one or more embodiments.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

As used in this specification and the appended claims, the terms “precursor,” “reactant,” “reactive gas” and the like are used interchangeably to refer to any gaseous species that can react with the substrate surface.

“Epitaxy” is a process by which a deposited film is forced into a high degree of crystallographic alignment with the substrate. Epitaxial growth is broadly defined as the condensation of gas precursors to form a film on a substrate. Liquid precursors may also be used. Vapor precursors may be obtained by chemical vapor deposition (CVD) and laser ablation. Several epitaxy techniques are now available, such as molecular beam epitaxy (MBE), epitaxial CVD, or atomic layer epitaxy (ALE).

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

As used herein, the term “field effect transistor” or “FET” refers to a transistor that uses an electric field to control the electrical behavior of the device. Enhancement mode field effect transistors generally display very high input impedance at low temperatures. The conductivity between the drain and source terminals is controlled by an electric field in the device, which is generated by a voltage difference between the body and the gate of the device. The FET's three terminals are source(S), through which the carriers enter the channel; drain (D), through which the carriers leave the channel; and gate (G), the terminal that modulates the channel's conductivity. Conventionally, entering the channel at the source(S) is designated Is and current entering the channel at the drain (D) is designated I_{D}. Drain-to-source voltage is designated VDs. By applying voltage to gate (G), the current entering the channel at the drain (i.e., I_{D}) can be controlled.

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p region. If the MOSFET is a p-channel or pMOS FET, then the source and drain are p+ regions and the body is an n region. The source is so named because it is the source of the charge carriers (electrons for n-channel, holes for p-channel) that flow through the channel; similarly, the drain is where the charge carriers leave the channel.

As used herein, the term “fin field-effect transistor (FinFET)” refers to a MOSFET transistor built on a substrate where the gate is placed on two or three sides of the channel, forming a double- or triple-gate structure. FinFET devices have been given the generic name FinFETs because the channel region forms a “fin” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nanowires or nano-slabs or nano-sheets, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

One example of gate-all-around (GAA) technology is complementary field effect transistor (CFET). As used herein, the term “complementary field-effect transistor (CFET)” refers to a transistor that includes NMOS FET devices and PMOS FET devices stacked on each other. Each of the NMOS FET devices and the PMOS FET devices that form the CFET are GAA transistors or hGAA transistors. CFET transistors have increased on-chip device density and reduced area consumption when compared to GAA transistors.

As used herein, the term “nanowire” refers to a nanostructure, with a diameter on the order of a nanometer (10-9 meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm.

Generally, front-end of line (FEOL) refers to the first portion of integrated circuit fabrication, including transistor fabrication, middle of line (MOL) connects the transistor and interconnect parts of a chip using a series of contact structures, and back-end of line (BEOL) refers to a series of process steps after transistor fabrication through completion of a wafer. One or more embodiments of the disclosure are directed to methods of forming gate-all-around (GAA) transistors that may be used in FEOL and/or BEOL processes.

The embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

One or more embodiments of the disclosure are described with reference to the Figures. In the method of one or more embodiments, transistors, e.g., gate all-around transistors, FinFETs, CFETS, NMOS, PMOS, and the like, are fabricated. In one or more embodiments, transistors, e.g., GAA device, are fabricated using a standard process flow. One or more of the Figures illustrate a part or a step of a multi-step fabrication process of a semiconductor device, specifically during backside power delivery (BPD).

Connecting semiconductors to a power rail is typically done on the front of the cell, which requires significant cell area. Backside power rail formation, connecting backside of source-epi (known as BPR Gen-II) for a logic transistor (e.g., a FinFET or GAA) has been explored for continued area scaling in next generation logic nodes.

Embodiments of the present disclosure advantageously provide new integration schemes that reduce backside contact over-etch. Some embodiments are directed to processes and integration schemes that advantageously use an inhibitor treatment on the sidewall liner and selective deposition of silicon-containing layers, e.g., silicon nitride, as an etch stop layer to prevent over-etch. The deposition of the silicon-containing layer is a bottom-up deposition on the front side of the contact trench from the front side of the wafer. In one or more embodiments, the silicon-containing layer is used as an etch stop layer when the wafer is flipped and subsequent backside contact trench etching is performed from the backside of the wafer.

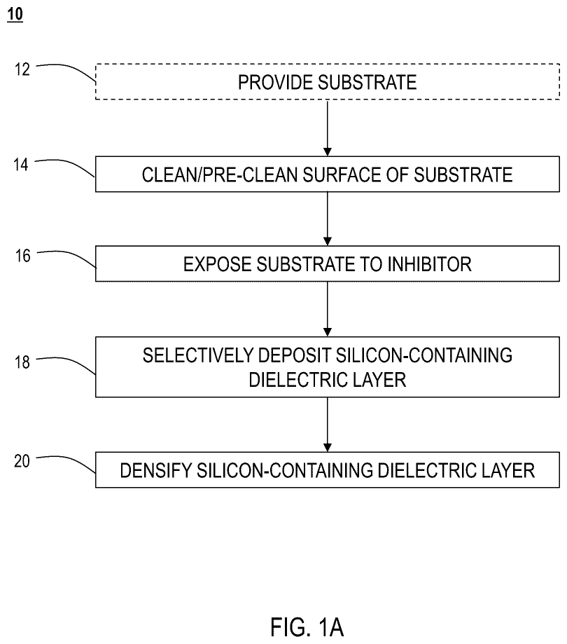

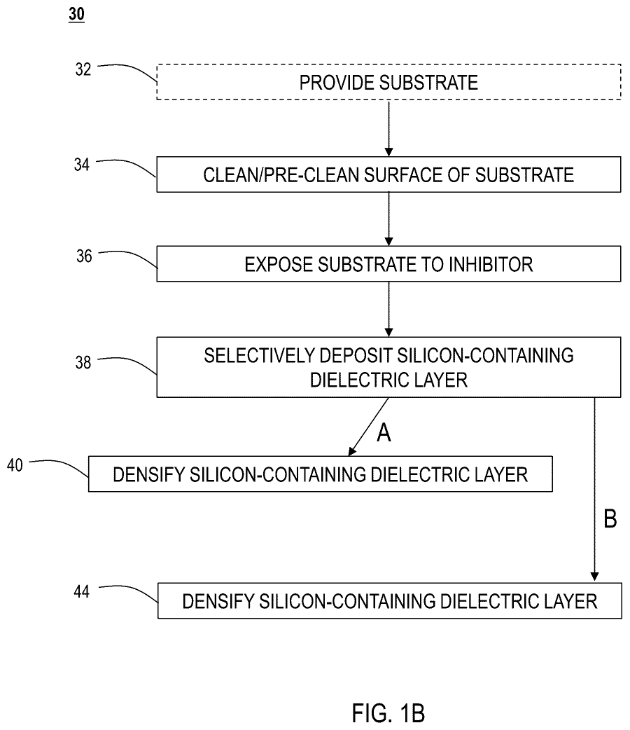

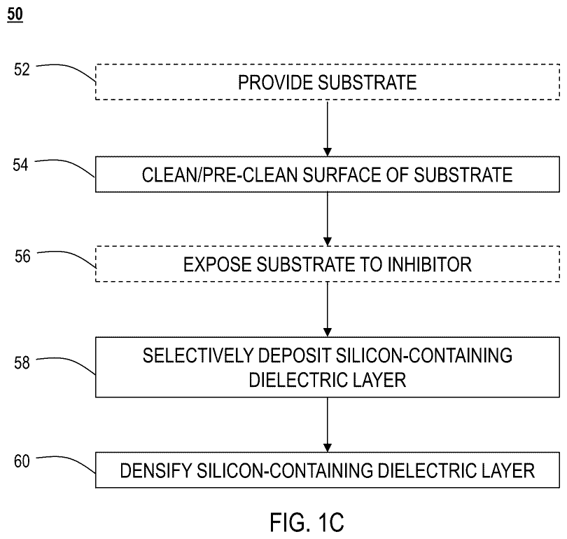

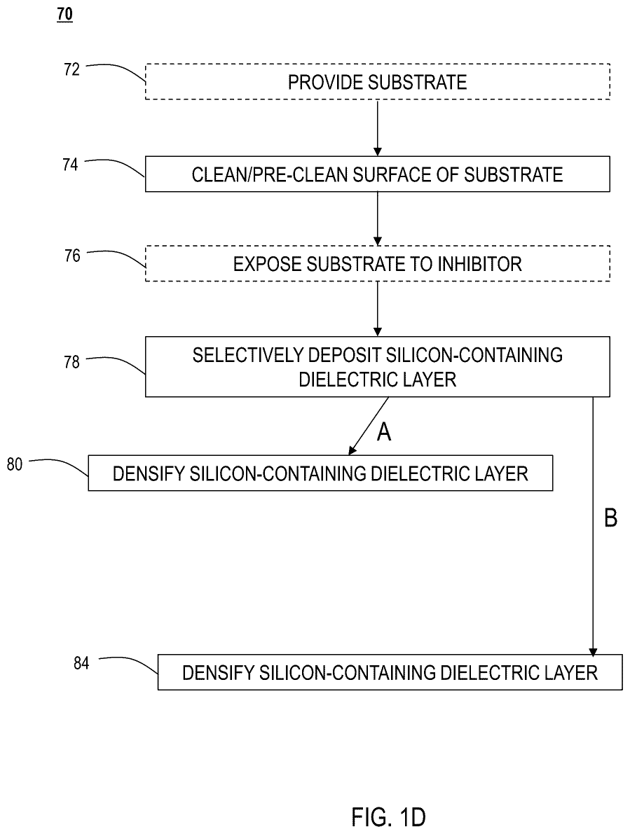

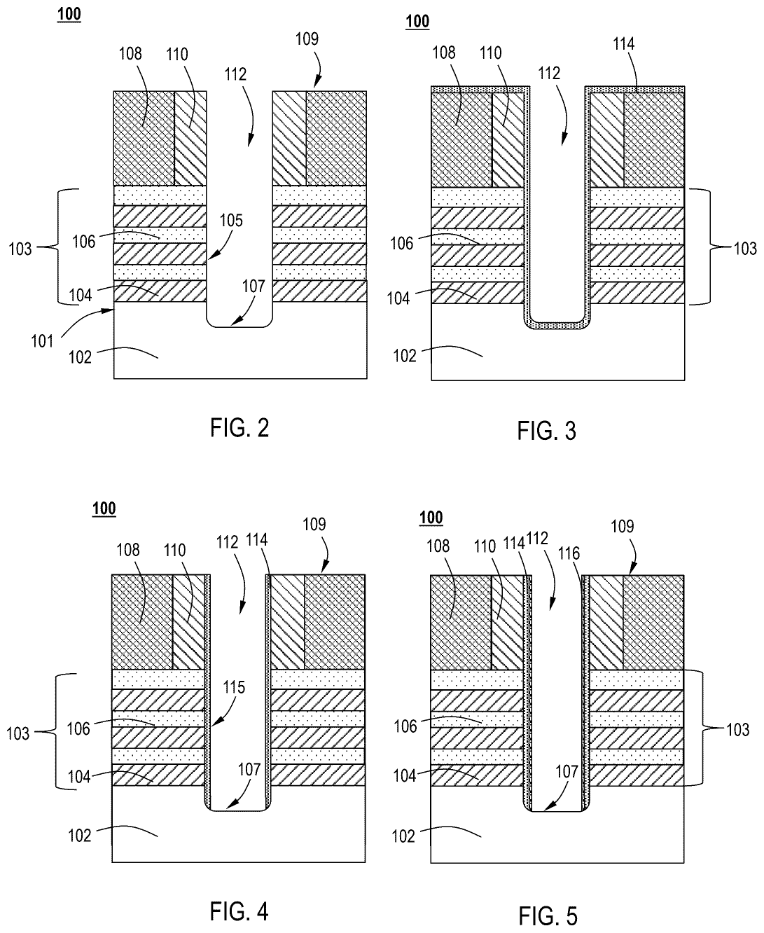

FIGS. 1A to 1D illustrate process flow diagrams for methods 10, 30, 50, and 70 for forming a semiconductor device 100 in accordance with one or more embodiments of the present disclosure. The methods of FIGS. 1A to 1D are described below with respect to FIGS. 2 to 11, which depict the stages of fabrication of semiconductor structures, specifically gate-all-around (GAA) devices in accordance with some embodiments of the present disclosure. The methods 10, 30, 50, and 70 of one or more embodiments may be part of a multi-step fabrication process of a semiconductor device. Accordingly, methods 10, 30, 50, and 70 may be performed in any suitable process chamber coupled to a cluster tool. The cluster tool may include process chambers for fabricating a semiconductor device, such as chambers configured for etching, deposition, atomic layer deposition (ALD), physical vapor deposition (PVD), chemical vapor deposition (CVD), oxidation, or any other suitable chamber used for the fabrication of a semiconductor device.

FIG. 1A illustrates a process flow diagram for an exemplary method 10 for forming a semiconductor device, e.g., a memory device or a logic device. The skilled artisan will recognize that the method 10 can include any or all of the processes illustrated. Additionally, the order of the individual processes can be varied for some portions. The method 10 can start at any of the enumerated processes without deviating from the disclosure. With reference to FIG. 1A, at operation 12, a substrate is provided. As used herein, the term “provided” means that the substrate is made available for processing (e.g., positioned in a processing chamber). At operation 14, the surface of the substrate is cleaned of any impurities, e.g., native oxide. At operation 16, the substrate is exposed to a growth inhibitor. At operation 18, a silicon-containing dielectric layer is selectively deposited in a region of the film stack. At operation 20, the silicon-containing dielectric layer is densified.

The method 10 of one or more embodiments is an integrated method. In one or more embodiments, the method 10 may be performed in one or more processing chamber without breaking vacuum between any of the operations 12, 14, 16, 18, and 20.

FIG. 1B illustrates a process flow diagram for an exemplary method 30 for forming a semiconductor device, e.g., a memory device or a logic device. The skilled artisan will recognize that the method 30 can include any or all of the processes illustrated. Additionally, the order of the individual processes can be varied for some portions. The method 30 can start at any of the enumerated processes without deviating from the disclosure. With reference to FIG. 1B, at operation 32, a substrate is provided. At operation 34, the surface of the substrate is cleaned of any impurities, e.g., native oxide. At operation 36, the substrate is exposed to a growth inhibitor. At operation 38, a silicon-containing dielectric layer is selectively deposited in a region of the device. The method 30 may then proceed by pathway A, where, at operation 40, the silicon-containing dielectric layer is densified. Alternatively, after operation 38, the method 30 may then proceed by pathway B, where, at operation 44, the silicon-containing dielectric layer is densified.

The method 30 of one or more embodiments is an integrated method. In one or more embodiments, the method 30 may be performed in one or more processing chamber without breaking vacuum between any of the operations 32, 34, 36, 38, and 40, or between any of the operations 32, 34, 36, 38, and 44.

FIG. 1C illustrates a process flow diagram for an exemplary method 50 for forming a semiconductor device, e.g., a memory device or a logic device. The skilled artisan will recognize that the method 50 can include any or all of the processes illustrated. Additionally, the order of the individual processes can be varied for some portions. The method 50 can start at any of the enumerated processes without deviating from the disclosure. With reference to FIG. 1C, at operation 52, a substrate is provided. At operation 54, the surface of the substrate is cleaned of any impurities, e.g., native oxide. At operation 56, the substrate optionally is exposed to a growth inhibitor. At operation 58, a silicon-containing dielectric layer is selectively deposited in a region of the film stack. At operation 60, the silicon-containing dielectric layer is densified.

The method 50 of one or more embodiments is an integrated method. In one or more embodiments, the method 50 may be performed in one or more processing chamber without breaking vacuum between any of the operations 52, 54, 56, 58, and 60.

FIG. 1D illustrates a process flow diagram for an exemplary method 70 for forming a semiconductor device, e.g., a memory device or a logic device. The skilled artisan will recognize that the method 70 can include any or all of the processes illustrated. Additionally, the order of the individual processes can be varied for some portions. The method 70 can start at any of the enumerated processes without deviating from the disclosure. With reference to FIG. 1D, at operation 72, a substrate is provided. At operation 74, the surface of the substrate is cleaned of any impurities, e.g., native oxide. At operation 76, the substrate is optionally exposed to a growth inhibitor. At operation 78, a silicon-containing dielectric layer is selectively deposited in a region of the device. The method 70 may then proceed by pathway A, where, at operation 80, the silicon-containing dielectric layer is densified. Alternatively, after operation 78, the method 70 may then proceed by pathway B, where, at operation 84, the silicon-containing dielectric layer is densified.

The method 70 of one or more embodiments is an integrated method. In one or more embodiments, the method 70 may be performed in one or more processing chamber without breaking vacuum between any of the operations 72, 74, 76, 78, and 80, or between any of the operations 72, 74, 76, 78, and 84.

Referring to FIGS. 1A to 1D and FIGS. 2 to 13, the method 10, 30, 50, and 70 begins at operation 12, 32, 52, and 72 by providing a substrate 102. In one or more embodiments, a superlattice structure 103 is formed on a top surface 101 of a semiconductor substrate 102.

In some embodiments, the substrate 102 may be a bulk semiconductor substrate. The term bulk semiconductor substrate refers to a substrate in which the entirety of the substrate is comprised of a semiconductor material. The bulk semiconductor substrate may comprise any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, or other suitable semiconducting materials. In some embodiments, the semiconductor material is silicon (Si). In some embodiments, the semiconductor material may be a doped material, such as n-doped silicon (n-Si), or p-doped silicon (p-Si). In some embodiments, the substrate may be doped using any suitable process such as an ion implantation process. In some embodiments, the substrate may be doped to provide a high dose of dopant at a first location of the surface of the substrate 102 in order to prevent parasitic bottom device turn on. The superlattice structure is formed atop the first location. For example, in some embodiments, the surface of the substrate may have a dopant density of about 10¹⁸ atoms/cm³ to about 10¹⁹ atoms/cm³.

With reference to FIG. 2, in some embodiments, a source/drain recess 112 is formed within the semiconductor substrate 102. The source/drain recess 112 may be formed from any suitable semiconductor material, such as but not limited to silicon (Si), germanium (Ge), silicon germanium (SiGe), or the like. In some embodiments, the source/drain recess 112 may be formed using any suitable deposition process, such as an epitaxial deposition process. In some embodiments, the source/drain recess 112 has a depth in a range of from 30 nm to 60 nm.

At least one superlattice structure 103 is formed atop the top surface 102a of the semiconductor substrate 102. The superlattice structure 103 is formed adjacent to the source/drain recess 112 formed within the semiconductor substrate 102. The superlattice structure 103 comprises a plurality of first layers 104 and a corresponding plurality of second layers 106 alternatingly arranged in a plurality of stacked pairs. In some embodiments the plurality of stacked groups of layers comprises a silicon (Si) and silicon germanium (SiGe) group.

In one or more embodiments, the plurality of first layers 104 comprises a first material and the corresponding plurality of second layers 106 comprises a second material. In or more embodiments, the first material comprises silicon germanium (SiGe) and the second material comprises silicon (Si). In other embodiments, the first material comprises silicon (Si) and the second material comprises silicon germanium (SiGe). In one or more embodiments, the plurality of first layers 104 and corresponding plurality of second layers 106 can comprise any number of lattice matched material pairs suitable for forming a superlattice structure. In one or more embodiments, the plurality of first layers 104 and corresponding plurality of second layers 106 comprise from 2 to 50 pairs, or from 2 to 20 pairs of lattice matched materials.

Typically, a parasitic device will exist at the bottom of the superlattice structure 103. In one or more embodiments, the implantation of a dopant in the substrate, as discussed above, is used to suppress the turn on of the parasitic device. In one or more embodiments, the substrate 102 is etched so that the bottom portion of the superlattice structure 103 includes a substrate portion which is not removed, allowing the substrate portion to act as the bottom release layer of the superlattice structure.

The thicknesses of the first layers 104 and second layers 106 in one or more embodiments are in the range of about 2 nm to about 50 nm, or in the range of about 3 nm to about 20 nm. In one or more embodiments, the average thickness of the first layers 104 is within 0.5 to 2 times the average thickness of the second layers 106.

In one or more embodiments, a dummy gate structure 108 is formed over the superlattice structure 103. The dummy gate structure 108 defines the channel region of the transistor device. The dummy gate structure 108 may be formed using any suitable conventional deposition and patterning process known in the art.

In one or more embodiments, sidewall spacers 110 are formed along outer sidewalls of the dummy gate structure 108. The sidewall spacers 110 of one or more embodiments comprise suitable insulating materials known in the art, for example, silicon nitride (SiN), silicon oxide (SiOx), silicon oxynitride (SiON), silicon carbide (SiC), or the like. In some embodiments, the sidewall spacers 110 are formed using any suitable conventional deposition and patterning process known in the art, such as atomic layer deposition, plasma enhanced atomic layer deposition, plasma enhanced chemical vapor deposition, or low-pressure chemical vapor deposition.

Referring to FIG. 3, in one or more embodiments, an oxide liner 114 is deposited in the source/drain recess 112 along the sidewalls 105 of the superlattice structure 103, on the top surface 109 of the dummy gate 108 and sidewall spacers 110, and on the bottom surface 107 of the source/drain recess 112. The oxide liner 114 may comprise any suitable material known to the skilled artisan. In one or more embodiment, the oxide liner 112 may include a material selected from silicon oxide (SiOx), silicon oxycarbide (SiOC), silicon carboxide (SiCOH), and the like. As used herein, terms such as “silicon oxide” refers to a material comprising silicon and oxygen. “Silicon oxide” should not be understood to imply any stoichiometric ratio. Stated differently, a dielectric material comprising silicon oxide may be stoichiometric or non-stoichiometric, silicon-rich, or silicon-poor.

With reference to FIG. 4, in one or more embodiments, the oxide liner 114 is opened to expose the top surface 109 of the dummy gate structure 108 and sidewall spacers 110, and to expose the bottom surface 107 of the source/drain recess 112. The oxide liner 114 may be removed by any suitable process known to the skilled artisan, including, but not limited to, reactive ion etching and planarization.

Referring to FIG. 5 and FIGS. 1A to 1D, at operation 14, 34, 54, and 74 the exposed surface(s), e.g., bottom surface 107, top surface 109, and sidewall surface 115 of the oxide liner 114 may be cleaned/pre-cleaned. In some embodiments, the clean/pre-clean process comprises a sublimation etch for native oxide removal. The etch process can be plasma or thermally based. The plasma processes can be any suitable plasma (e.g., conductively coupled plasma, inductively coupled plasma, microwave plasma). In one or more embodiments, the clean process may include a conventional plasma etch, or a remote plasma-assisted dry etch process. In a remote plasma-assisted dry etch process of one or more embodiments, the device 100 is exposed to H₂, NF₃, and/or NH₃ plasma species, e.g., plasma-excited hydrogen and fluorine species. For example, in some embodiments, the device 100 may undergo simultaneous exposure to H₂, NF₃, and NH₃ plasma. The remote plasma-assisted dry etch process may be performed in any suitable preclean chamber, which may be integrated into one of a variety of multi-processing platforms. The wet etch process of one or more embodiments may include a hydrofluoric (HF) acid last process, i.e., the so-called “HF last” process, in which HF etching of the surface is performed that leaves the surface hydrogen-terminated. Alternatively, any other liquid-based pre-clean process may be employed.

With reference to FIG. 5 and FIGS. 1A to 1D, in one or more embodiments, at operation 16, 36, 56, and 76 the semiconductor device 100 is exposed to a growth inhibitor to avoid deposition. The growth inhibitor may be added on the sidewall surface 115 of the oxide liner 114 to prevent deposition on the oxide liner 114. In some embodiments, as illustrated in method 50 of FIG. 1C, exposing the semiconductor device 100 to a growth inhibitor is optional.

In one or more embodiments, a surface treatment, e.g., exposure to a growth inhibitor, is used to ensure that different terminating groups are present on the sidewall surface 115 of the oxide liner 114 than on the bottom surface 107 of the source/drain recess 112 so that a subsequent ALD of CVD film growth will be differentiated based on the difference surfaces. For example, to prepare a bare Si surface terminated with Si—H groups, dilute HF wet clean, a dry clean, or a plasma-based dry clean can be used to remove native oxide on Si surface and form Si—H bonds. To prepare a passivated surface that can block ALD film growth, a hydrophobic surface monolayer can be formed on silicon oxide surface. For example, alkylamino silane can be adsorbed onto silicon oxide surface to form alkylsilyl groups on SiO surface. The ALD film growth chemistry of some embodiments is based on silicon halide and ammonia reactions which can selectively grow on bare Si surface but not a passivated SiO surface. The maximum thickness achievable by some embodiments is about 100 Å growth on bare Si, with substantially no film growth on the passivated SiO surface. Periodic SiO and/or SiOC surface regeneration and passivation could be used to make thicker growth on bare Si than SiO.

Referring to FIG. 5, in accordance with one or more embodiments of the disclosure, exposure to a growth inhibitor may involve the formation of a blocking layer 116 having a hydroxyl-terminated surface on the sidewall surface 115 of the oxide liner 114, while the bottom surface 107 of the source/drain recess 112 may have a hydrogen-terminated surface. In some unillustrated embodiments, the sidewall surface 115 of the oxide liner 114 and the bottom surface 107 of the source/drain recess 112 may also have some native oxide formed thereon. Those skilled in the art will understand that the surface atom bonding is not always simple. For example, an oxide surface can be a bridged oxygen atom bonded to more than one silicon atom and the stoichiometry of the surface and bulk composition are not necessarily one-to-one.

The sidewall surface 115 of the oxide liner 114 and the bottom surface 107 of the source/drain recess 112 can be any suitable surfaces for selective deposition. In some embodiments, the sidewall surface 115 of the oxide liner 114 is a dielectric surface with —OH ending groups and the bottom surface 107 of the source/drain recess 112 comprises a silicon surface with Si—H groups with or without native oxide. In some embodiments, the bottom surface 107 of the source/drain recess 112 comprises a dielectric surface with —OH ending groups and the sidewall surface 115 of the oxide liner 114 comprises a silicon surface with Si—H groups with or without native oxide.

If a native oxide is present on the sidewall surface 115 of the oxide liner 114 and the bottom surface 107 of the source/drain recess 112, removal of the native oxide may allow for a more effective selective deposition process. Exposing the device 100 to an etch process can remove the native oxide from the sidewall surface 115 of the oxide liner 114 and the bottom surface 107 of the source/drain recess 112. The etch process can be a wet etch process (e.g., exposure to dilute HF (1%)) or a dry etch process (e.g., exposure to a plasma). In some embodiments, the etch process is a plasma-based process. In some embodiments, the plasma-based etch process comprises exposing the substrate to a plasma of ammonia and hydrofluoric acid.

In some embodiments, removing the native oxide from the sidewall surface 115 of the oxide liner 114 and the bottom surface 107 of the source/drain recess 112 provides a surface with substantially only hydrogen terminations. As used in this manner, the term “substantially only hydrogen terminations” means that the surface terminations are hydrogen for greater than or equal to about 98% of the surface area. In some embodiments, removing the native oxide from the sidewall surface 115 of the oxide liner 114 and the bottom surface 107 of the source/drain recess 112 provides a surface with substantially no oxygen terminations. As used in this manner, the term “substantially no oxygen terminations” means that the surface terminations comprise less than about 2% of the surface area comprises oxygen atoms.

In one or more embodiments, the process used to remove the native oxides from the sidewall surface 115 of the oxide liner 114 also oxidizes the bottom surface 107 of the source/drain recess 112 to provide a surface with substantially no hydrogen terminations. As used in this manner, the term “substantially no hydrogen terminations” means that the surface terminations of the stated surface are hydrogen for less than or equal to about 2% of the surface area. In some embodiments, the sidewall surface 115 of the oxide liner 114 comprises substantially only hydroxyl terminations. As used in this manner, the term “substantially only hydroxyl terminations” means that the surface terminations for the subject surface are hydroxyl groups for greater than or equal to about 98% of the surface area.

The device, including the sidewall surface 115 of the oxide liner 114 and the bottom surface 107 of the source/drain recess 112, can be exposed to a growth inhibitor to react with the hydroxyl-terminated surface to form a blocking layer 116. The growth inhibitor of some embodiments comprises an alkylsilane. In some embodiments, has a general formula SiR₄, where each R is independently a C₁-C₆ alkyl, a substituted or unsubstituted amine, a substituted or unsubstituted cyclic amine.

In some embodiments, the alkylsilane comprises substantially no Si—H bonds. As used in this manner, the term “substantially no Si—H bonds” means that the growth inhibitor comprises less than about 1% Si—H bonds based on the total number of silicon bonds. The growth inhibitor of some embodiments, forms surface termination-OSiRx on the sidewall surface 115 of the oxide liner 114 and the bottom surface 107 of the source/drain recess 112, replacing the —OH terminations. In some embodiments, the growth inhibitor comprises s one or more of 1-(trimethylsilyl) pyrrolidine or bis(dimethylamino)dimethylsilane.

In one or more embodiments, the alkylsilane comprises at least one substituted or unsubstituted cyclic amine with a ring having in the range of 4 to 10 atoms. In some embodiments, the alkylsilane comprises a cyclic amine that has one nitrogen atom. In some embodiments, the cyclic amine has no more than one nitrogen atom and no less than one nitrogen atom. In one or more embodiments, the cyclic amine comprises pyrrolidine in which the nitrogen atom of the pyrrolidine is bonded to the silicon atom of the alkylsilane. In some embodiments, the alkylsilane comprises 1-(trimethylsilyl) pyrrolidine. In one or more embodiments, the alkylsilane consists essentially of 1-(trimethylsilyl) pyrrolidine. As used in this manner, the term “consists essentially of” means that the alkylsilane is greater than or equal to about 98% 1-(trimethylsilyl) pyrrolidine on a molecular basis.

The device 100 can be exposed to the growth inhibitor at any suitable temperature and pressure. In one or more embodiments, the device 100 is exposed to the growth inhibitor at a temperature in the range of about 50° C. to about 500° C., or in the range of about 100° C. to about 400° C. In some embodiments, the device 100 is exposed to the growth inhibitor at a pressure in the range of about 30 Torr to about 120 Torr, or in the range of about 40 Torr to about 100 Torr, or in the range of about 50 Torr to about 90 Torr. In one or more embodiments, the device 100 is exposed to the growth inhibitor in a thermal process without plasma.

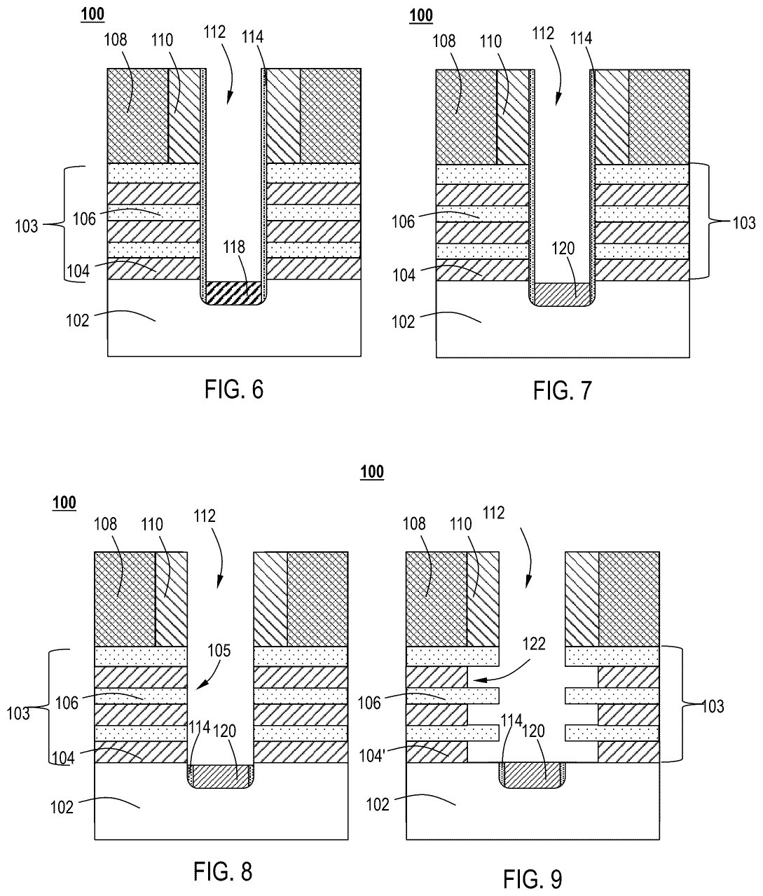

Referring to FIG. 6 and FIGS. 1A to 1D, in one or more embodiments, at operation 18, 38, 58, and 78 a silicon-containing dielectric layer 118 may be selectively deposited on the bottom surface 107 of the source/drain recess 112 and not (or substantially not) on the oxide layer 114. The silicon-containing dielectric layer 118 may be deposited by any suitable means known to the skilled artisan. In one or more embodiments, the silicon-containing dielectric layer 118 is deposited, e.g., atomic layer deposition (ALD) or chemical vapor deposition (CVD), at a temperature less than 500° C.

The silicon-containing dielectric layer 118 may comprise any suitable material dielectric material known to the skilled artisan. As used herein, the term “dielectric material” refers to a layer of material that is an electrical insulator that can be polarized in an electric field. In one or more embodiments, the silicon-containing dielectric layer 118 comprises one or more of silicon nitride (SiN), silicon carbonitride (SiCN), silicon oxynitride (SiON), silicon oxycarbonitride (SiOCN), silicon boride (SiB), and silicon boron nitride (SiBN). In specific embodiments, the silicon-containing dielectric layer 118 comprises silicon nitride (SiN).

In one or more embodiments, deposition of the silicon-containing dielectric layer 118 is selective to the bottom surface 107 of the source/drain recess 112 over the sidewall surface 115 of the oxide layer 114, such that the silicon-containing dielectric layer 118 deposits on the bottom surface 107 of the source/drain recess 112 and not (or substantially not) on the oxide liner 114. As used in this regard, the term “selectively over” means that the film is formed on the bottom surface 107 of the source/drain recess 112 to a greater extent than the film can be formed on the oxide layer 114. For example, the silicon-containing dielectric layer 118 can be formed on the bottom surface 107 of the source/drain recess 112 greater than or equal to 20 times, 30 times, 40 times, or 50 times thicker than the film is formed on the oxide liner 114. It one or more embodiments, the selectivity is greater than 2:1, greater than 5:1, greater than 10:1, or greater than 100:1.

In one or more embodiments, the silicon-containing dielectric layer 118 has a thickness in a range of from greater than 0 Å to 200 Å.

Without intending to be bound by theory, it is thought that the relatively low deposition temperature (i.e., less than 500° C.) leads to a poor-quality silicon-containing dielectric layer 118. Accordingly, the poor-quality silicon-containing dielectric layer 118 has a poor wet etch rate (WER) of greater than 300 Å.

Formation of the silicon-containing dielectric layer 118 can occur by any suitable technique including, but not limited to, atomic layer deposition. In one or more embodiments, the silicon-containing dielectric layer 118 is formed in a single processing chamber. In other embodiments, the silicon-containing dielectric layer 118 is formed in a batch processing chamber, like that shown in FIG. 14. For example, the silicon-containing dielectric layer 118 may be formed by sequential exposure to a silicon precursor and a reactant. The silicon-containing dielectric layer 118 of some embodiments comprises one or more of SiN, SiO, SiON, SiC, SiCO, SiCN, or SiCON. In some embodiments, the silicon-containing dielectric layer 118 comprises silicon and one or more of oxygen, carbon, or nitrogen atoms. In some embodiments, the silicon-containing dielectric layer 118 is doped with one or more of boron (B), arsenic (As), or phosphorus (P) in an amount up to about two percent on an atomic basis.

In some embodiments, the silicon precursor comprises a silicon halide, and the reactant comprises ammonia. In some embodiments, the silicon precursor comprises an organic silicon compound with or without halogen atoms. In some embodiments, the reactant comprises a nitrogen contributing species, an oxygen contributing species and/or a carbon contributing species. In some embodiments, the silicon precursor contributes one or more of nitrogen, oxygen, or carbon to the silicon-containing dielectric layer 118.

In one or more embodiments, the silicon-containing dielectric layer 118 is deposited using ALD or CVD, where the bottom surface 107 of the source/drain recess 112 is exposed to a silicon precursor and ammonia to form the silicon-containing dielectric layer 118 on the bottom surface 107 of the source/drain recess 112. The silicon precursor may include any suitable silicon precursor known to the skilled artisan. In one or more embodiments, the silicon precursor comprises a silane (SiH₄) or a poly-silane (SiₓH_{y}). In some embodiments, the poly-silane is selected from disilane (Si₂H₆), trisilane (Si₃H₈), tetrasilane (Si₄H₁₀), isotetrasilane, neopentasilane (Si₅H₁₂), cyclopentasilane (Si₅H₁₀), hexasilane (C₆H₁₄), and cyclohexasilane (Si₆H₁₂).

In a single processing chamber, the substrate can be exposed to the silicon precursor and reactant in the same process region of the processing chamber. In a batch processing chamber, the substrate can be exposed to the silicon precursor and reactant in alternating process regions of the processing chamber.

The silicon-containing dielectric layer 118 thickness can be deposited to a predetermined amount. After some time, the silicon-containing dielectric layer 118 may begin to deposit on the sidewall surface 115 of the oxide liner 114 even though the blocking layer 116 (from the growth inhibitor) is present. Without intending to be bound by any particular theory of operation, it is believed that the blocking layer 116 may be removed by the repeated exposures to the deposition reactants. To increase the thickness of the silicon-containing dielectric layer 118 and maintain the selectivity, the blocking layer 116 may be replenished periodically. In some embodiments, the device 100 is exposed to the growth inhibitor after no more than 20, 30, 40, 50, 60, 70, 80, 90 or 100 atomic layer deposition cycles to deposit the silicon-containing dielectric layer 118. In some embodiments, the device 100 is exposed to the growth inhibitor after formation of the silicon-containing dielectric layer 118 to a thickness in the range of about 30 Å to about 100 Å, or after formation of the silicon-containing dielectric layer 118 to a thickness up to about 20 Å, 30 Å, 40 Å, 50 Å, 60 Å or 70 Å.

Regeneration of the blocking layer 116 can be done by any suitable process. For example, the surface of the device can be purged with an inert gas (e.g., N₂ or He) for a time in the range of about 10 minutes to about 60 minutes at a pressure in the range of about 1 Torr to about 30 Torr. After purging the surface, the device can be exposed to the growth inhibitor again to regenerate the blocking layer 116. In some embodiments, the surface is purged for a time in the range of about 15 minutes to about 50 minutes, or a time in the range of about 20 minutes to about 40 minutes. In some embodiments, the surface is purged at a pressure in the range of about 10 Torr to about 25 Torr, or in the range of about 15 Torr to about 20 Torr.

In some embodiments, the blocking layer 116 is regenerated by first etching the whole surface followed by exposure to the growth inhibitor. The etching process can be the same process used to pre-clean the surface or can be a different etching process.

The silicon-containing dielectric layer 118 can be formed at any suitable temperature. In some embodiments, the silicon-containing dielectric layer 118 is formed at a temperature in the range of about 200° C. to about 700° C., or in the range of about 300° C. to about 500° C., or in the range of about 350° C. to about 450° C. In some embodiments, the silicon-containing dielectric layer 118 is formed by a thermal process without plasma exposure. In one or more embodiments, thermal methods are used to selectively deposit the silicon-containing dielectric layer 118. In specific embodiments, the thermal process is performed without a plasma and without forming a seed layer. In other words, the silicon-containing dielectric layer 118 is selectively deposited directly on the bottom surface 107 of the source/drain recess 112 without the deposition of an intervening layer of material. As used herein, “seed layer” refers to layer that is deposited directly on the bottom surface 107 of the source/drain recess 112 to promote the subsequent formation/growth of a bulk layer thereon. In some cases, a bulk layer cannot be deposited directly on the bottom surface 107 of the source/drain recess 112 without the deposition of an intervening layer of material, in which case a seed layer is required to enable bulk deposition. Advantageously, in one or more embodiments, the silicon-containing dielectric layer 118 is deposited directly on the bottom surface 107 of the source/drain recess 112 as a bulk layer without the deposition of an intervening layer of material. In other embodiments, the silicon-containing dielectric layer 118 is formed by a plasma enhanced process.

The silicon-containing dielectric layer 118 deposited may have film properties that can be optimized or improved by post-deposition processing. For example, a silicon nitride film deposited may have a high wet etch rate. Exposing the film to a post-deposition process can be used to improve the wet etch rate of the deposited the silicon-containing dielectric layer 118. In some embodiments, the post-deposition process improves a quality of the film. In some embodiments, the quality of the film improved comprises one or more of the wet etch rate, refractive index, density, or hydrogen concentration.

The post-deposition process of some embodiments comprises exposing the substrate surface to a decoupled plasma. The decoupled plasma of one or more embodiments comprises helium. In some embodiments, the decoupled plasma consists essentially of helium. As used in this regard, the term “consists essentially of helium” means that the plasma comprises greater than or equal to about 95 atomic percent helium. The treatment pressure of some embodiments is in the range of about 1 mTorr to about 1 Torr. Lower pressures may be used for isotropic treatment of high aspect ratio structures. Wafer temperature during treatment can range from about room temperature to about 500° C.

In some embodiments, the processing platform has an environment that does not readily oxidize the substrate surface after cleaning. As used in this regard, the term “environment” refers to the ambient conditions within at least the central transfer station. The environment of the processing platform of some embodiments also includes any processing chamber used in the deposition process. For example, if two processing chambers are used in the process, the “environment” might include the two processing chambers and the central transfer station. In some embodiments, the environment of the processing platform comprises water vapor. The water vapor can be mixed with an inert gas or neat. In some embodiments, the water vapor is present in an inert gas in an amount in the range of about 0.1% to about 90% by weight. In some embodiments, the water vapor is present in an amount in the range of about 1% to about 80%, or in the range of about 2% to about 70%, or in the range of about 3% to about 60%, or in the range of about 4% to about 50%, or in the range of about 5% to about 40%, or in the range of about 10% to about 20% by weight. In some embodiments, the environment comprises one or more of nitrogen, hydrogen, helium, argon, krypton, neon, or xenon with water vapor in an amount greater than or equal to about 0.1%, 0.5%, 1%, 2%, 3%, 4%, 5%, 6%, 7%, 8%, 9%, 10%, 12%, 14%, 16%, 18%, or 20%.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system,” and the like.

FIG. 7 shows operation 20 of FIG. 1A, operation 40 or operation 46 of FIG. 1B, operation 60 of FIG. 1C, and operation 80 or operation 86 of FIG. 1D, in which the silicon-containing dielectric layer 116 is densified to form a high-quality densified silicon-containing dielectric layer 120.

The silicon-containing dielectric layer 118 may be densified by any suitable means known to the skilled artisan. In one or more embodiments, the silicon-containing dielectric layer 118 is densified by one or more of a thermal process or other treatment without adding oxygen into the silicon-containing dielectric layer 120. In one or more embodiments, the silicon-containing dielectric layer 118 is exposed to rapid thermal processing (RTP) to provide the high-quality densified silicon-containing dielectric layer 120. In other embodiments, densifying the silicon-containing dielectric layer 118 comprises exposing the silicon-containing dielectric layer 118 to a high-density plasma at a temperature less than or equal to 500° C. and at a pressure less than 1 Torr. The high-density plasma may be selected from one or more of helium (He), hydrogen (H₂), nitrogen (N), neon (Ne), argon (Ar), krypton (Kr), and xenon (Xe).

In one or more embodiments, at operation 20, the selectively deposited silicon-containing dielectric layer 118 is densified at a temperature greater than 800° C. to provide a densified silicon-containing dielectric layer 120. In some embodiments, the silicon-containing dielectric layer 118 is treated at a temperature greater than 1000° C. to provide the densified silicon-containing dielectric layer 120. In one or more embodiments, after treatment, the silicon-containing dielectric layer 120 is a high-quality film and has a wet etch rate of less than 4 Å/min, including a wet etch rate of less than 3 Å/min, less than 2 Å/min, and less than 1 Å/min.

In one or more embodiments, the densified silicon-containing dielectric layer 120 has a density gradient in a range if from 2.2 g/cm³ to 3.2 g/cm³. As used herein, the term “gradient” refers to variation in density throughout a thickness of a material. In other words, the densified silicon-containing dielectric layer 120 has a density gradient in which the density of the densified silicon-containing dielectric layer 120 gradually changes from least dense portion of the film adjacent the surface deposited upon (i.e., bottom surface 107 of the source/drain recess 112).

In one or more embodiments, the densified silicon-containing dielectric layer 120 has a thickness in a range of from greater than 20 Å to less than 100 Å at the area of least density closest to the bottom surface 107 of the source/drain recess 112. In one or more embodiments, the densified silicon-containing dielectric layer 120 has a thickness in a range of from 5 Å to 25 Å at the area of greatest density furthest from the bottom surface 107 of the source/drain recess 112.

The method of one or more embodiments is an integrated method. In one or more embodiments, the method may be performed in one or more processing chamber without breaking vacuum.

With reference to FIGS. 8 to 12, formation of the device, e.g., a gate-all-around (GAA), may then proceed via traditional means. With reference to FIG. 8, the oxide liner 114 is removed from the device 100, exposing the sidewall surface 105 of the superlattice structure 103. The oxide liner 114 may be removed by any suitable means known to the skilled artisan. In one or more embodiments, the oxide liner 114 is removed by one of or more of etching or planarization.

Referring to FIG. 9, the method includes laterally etching each of the plurality of first layers 104 to form a plurality of recessed first layers 104′ having a recessed region 122 adjacent to the recessed first layers 104′ and adjacent to the source/drain recess 112.

For example, where the superlattice structure 103 is composed of a plurality of second layers 106 comprising silicon (Si) and a plurality of first layers 104 comprising silicon germanium (SiGe), the plurality of first layers 104 are laterally etched to form the plurality of recessed first layers 104′. The plurality of first layers 104 may be laterally etched using any known etchant that is selective to the plurality of first layers 104, where the etchant etches the plurality of first layers 104 at a significantly higher rate than the plurality of second layers 106. In some embodiments, a selective dry etch or wet etch process may be used. In one or more embodiments, the dry etch process includes exposing the plurality of first layers 104 to common gases for etching the silicon, reactive ion etching (RIE) with a remote plasma source, ammonia (NH₃), nitrogen trifluoride (NF₃), and hydrogen (H₂). In some embodiments, the plurality of first layers 104 may be etched using a wet etchant such as, but not limited to aqueous carboxylic acid/nitric acid/HF solution and aqueous citric acid/nitric acid/HF solution.

In one or more embodiments, each of the plurality of recessed first layers 104′ has a recessed region 122 with a recessed amount relative to the plurality of first layers 104 prior to etching. Stated differently, the recessed amount refers to the amount of first material that is removed from the plurality of first layers 104 to form the plurality of recessed first layers 104′. In some embodiments, each of the plurality of recessed first layers 104′ has a recessed amount in a range of 1 nm to 4 nm. In some embodiments, the recessed amount is 3 nm.

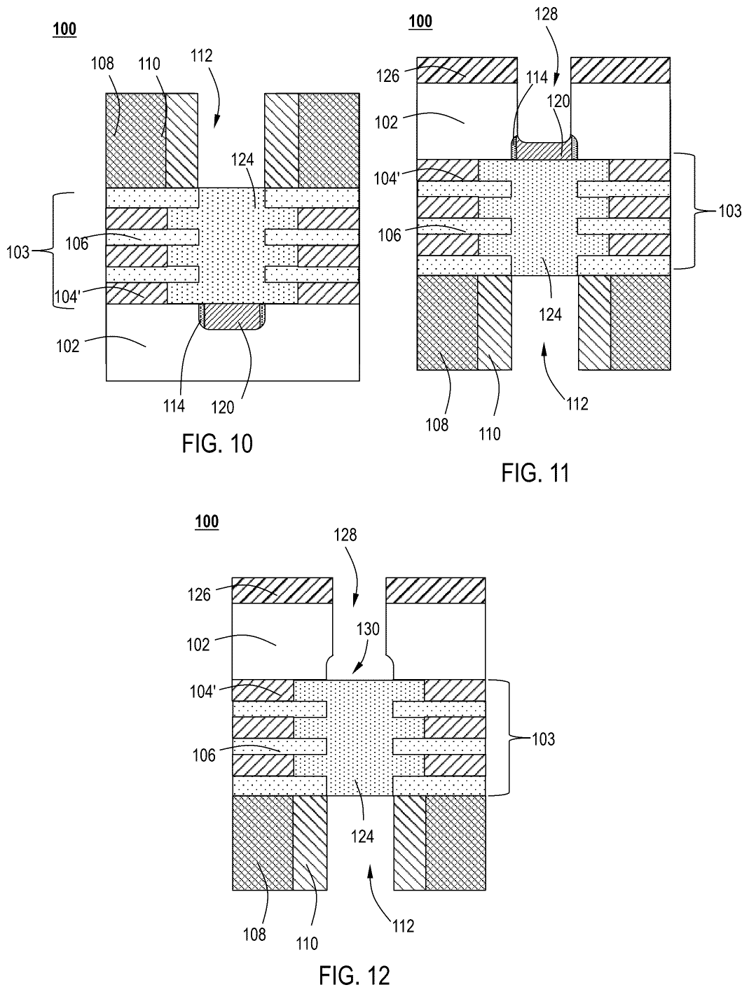

Referring to FIG. 10, the method includes epitaxially growing a source/drain layer 124 on the densified and/or oxidized silicon-containing dielectric layer 120. The epitaxial growth process may include any suitable deposition process, such as those described herein.

In some embodiments, the source/drain layer 124 has any suitable thickness. In some embodiments, the source/drain layer 124 fills some of the top portion of the source/drain recess 112. In some embodiments, the source/drain layer 124 fills the entirety of the top portion of the source/drain recess 112. Stated differently, in some embodiments, the source/drain layer 124 fills the depth of the top portion of the source/drain recess 112, which may be defined by the height of the superlattice structure 103 (the total thickness of 2 to 50 pairs, or from 2 to 10 pairs of lattice matched materials).

Completion of the frontside processing proceeds according to standard processing known to those of skill in the art. The device then undergoes wafer 126 bonding and is flipped to proceed with backside power processing. In one or more embodiments, the device undergoes grinding and thinning according to standard processing known to those of skill in the art.

With reference to FIG. 11, an opening 128 over the source/drain layer 124 is etched. The opening 128 may be formed by any suitable means known to the skilled artisan. In one or more embodiments, the silicon-containing dielectric layer 120 advantageously serves as an etch stop for the formation of the opening 128, reducing backside contact over-etch.

With reference to FIG. 12, the silicon-containing dielectric layer 120 and the remaining oxide liner 114 is then removed and backside processing proceeds via standard processing means.

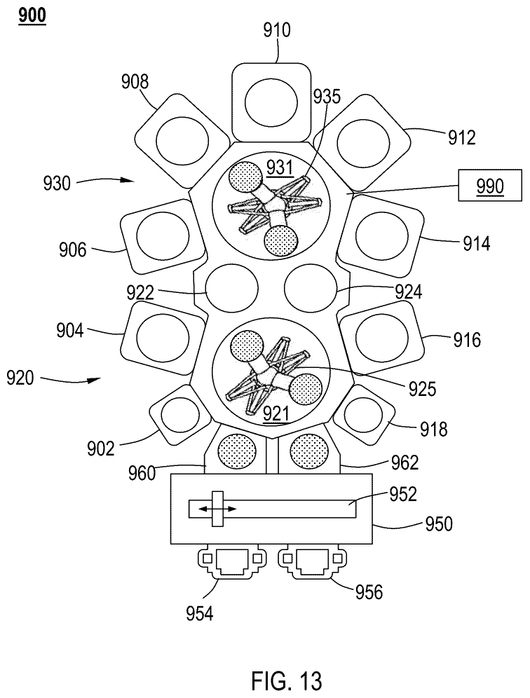

Additional embodiments of the disclosure are directed to processing tools 900 for the formation of the logic or memory devices and methods described, as shown in FIG. 13.

In one or more embodiments, the processing tool 900 is a cluster tool that includes at least one central transfer station, e.g., first transfer chamber 921, and second transfer chamber 931, with a plurality of sides. At least one robot 925, 935 is positioned within the at least one central transfer station, e.g., first transfer chamber 921, and second transfer chamber 931, and is configured to move a robot blade and a wafer to each of the plurality of sides.

In one or more embodiments, the processing tool 900 is a cluster tool that comprises a plurality of processing chambers 902, 904, 906, 908, 910, 912, 914, 916, and 918, also referred to as process stations, connected to the central transfer station. The various processing chambers provide separate processing regions isolated from adjacent process stations. The processing chamber can be any suitable chamber including, but not limited to, a preclean chamber, an inhibitor soaking chamber, a selective deposition (ALD) chamber, and a densification chamber (RTP). The particular arrangement of process chambers and components can be varied depending on the cluster tool and should not be taken as limiting the scope of the disclosure.

In the embodiment shown in FIG. 13 a factory interface 950 is connected to the front of the processing tool 900. The factory interface 950 includes a loading chamber 954 and an unloading chamber 956 on the front of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the processing tool 900, e.g., a cluster tool. In the embodiment shown, the loading chamber 954 and unloading chamber 956 are sized to hold a wafer cassette with a plurality of wafers positioned within the cassette.

A robot 952 is within the factory interface 950 and can move between the loading chamber 954 and the unloading chamber 956. The robot 952 is capable of transferring a wafer from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock chamber 962 and the unloading chamber 956.

In one or more embodiments, the processing tool 900 is a cluster tool that has a first section 920 and a second section 930. The first section 920 is connected to the factory interface 950 through load lock chambers 960, 962. The first section 920 includes a first transfer chamber 921 with at least one robot 925 positioned therein. The at least one robot 925 is also referred to as a robotic wafer transport mechanism. The first transfer chamber 921 is centrally located with respect to the load lock chambers 960, 962, processing chambers 902, 904, 916, 918, and buffer chambers 922, 924. The at least one robot 925 of some embodiments is a multi-arm robot capable of independently moving more than one wafer at a time. In some embodiments, the first transfer chamber 921 comprises more than one robotic wafer transfer mechanism. The at least one robot 925 in first transfer chamber 921 is configured to move wafers between the chambers around the first transfer chamber 921. Individual wafers are carried upon a wafer transport blade that is located at a distal end of the first robotic mechanism.

After processing a wafer in the first section 920, the wafer can be passed to the second section 930 through a pass-through chamber. For example, chambers 922, 924 can be uni-directional or bi-directional pass-through chambers. The pass-through chambers 922, 924 can be used, for example, to cryo cool the wafer before processing in the second section 930 or allow wafer cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit, memory, suitable circuits, and storage.

Processes may generally be stored in the memory of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware such as, e.g., an application specific integrated circuit or other type of hardware implementation, or as a combination of software and hardware. The software routine, when executed by the processor, transforms the general-purpose computer into a specific-purpose computer (controller) that controls the chamber operation such that the processes are performed.

In some embodiments, the system controller 990 has a configuration to control the selective deposition chamber to selectively deposit a silicon-containing dielectric layer in the source/drain region, at a temperature less than 500° C. In some embodiments, the system controller 990 has a configuration to activate the plasma treatment chamber expose the silicon-containing dielectric layer to thermally treat the silicon-containing dielectric layer at a temperature greater than 800° C. to provide a densified silicon-containing dielectric layer having a wet etch rate of less than 4 Å/min.

In one or more embodiments, a processing tool comprises: a central transfer station comprising a robot configured to move a wafer; a plurality of process stations, each process station connected to the central transfer station and providing a processing region separated from processing regions of adjacent process stations, the plurality of process stations comprising one or more of a pre-cleaning chamber, an inhibitor soaking chamber, a selective deposition chamber, a densification chamber, an oxidation chamber, and a controller connected to the central transfer station and the plurality of process stations, the controller configured to activate the robot to move the wafer between process stations, and to control a process occurring in each of the process stations. In one or more embodiments, the controller causes the processing tool to perform the operations of: pre-clean a surface of an oxide liner on a substrate having a source/drain region; expose the oxide liner to a growth inhibitor; selectively deposit a silicon-containing dielectric layer in the source/drain region of the substrate; and densify the silicon-containing dielectric layer. The processing tool is maintained under vacuum.

Spatially relative terms, such as “beneath,” “below,” “lower,” “above,” “upper” and the like, may be used herein for ease of description to describe one element's relationship to another element(s) or as illustrated in the Figures. It will be understood that the spatially relative terms are intended to encompass different orientations of a device, such as a semiconductor device, in use or operation in addition to the orientation depicted in the Figures. For example, if the device in the Figures is turned over, elements described as “below,” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments,” “some embodiments,” or “an embodiment” means that a particular element, structure, material, or characteristic described in connection with the embodiment is included in at least one embodiment of the disclosure. Thus, the instances in which the phrases such as “in one or more embodiments,” “in certain embodiments,” “in one embodiment,” “in some embodiments,” or “in an embodiment” used in various places throughout this specification are not necessarily referring to the same embodiment of the disclosure. In one or more embodiments, the particular elements, structures, materials, or characteristics are combined in any suitable manner.

What is claimed is:

1. A processing method to form a logic or memory device, the processing method comprising:
selectively depositing a silicon-containing dielectric layer in a source/drain recess on a substrate and through an opening in an oxide liner within the source drain recess; and
densifying the silicon-containing dielectric layer.

2. The processing method of claim 1, further comprising exposing the oxide liner to a growth inhibitor prior to selectively depositing the silicon-containing dielectric layer.

3. The processing method of claim 1, wherein the processing method is performed in a processing tool without breaking vacuum, and wherein the processing tool is selected from the group consisting of a single processing chamber and a batch processing chamber.

4. The processing method of claim 1, wherein densifying the silicon-containing dielectric layer forms a densified silicon-containing dielectric layer having a density gradient.

5. The processing method of claim 1, wherein the silicon-containing dielectric layer comprises one or more of silicon nitride (SiN), silicon carbonitride (SiCN), silicon oxynitride, silicon oxycarbonitride (SiOCN), silicon boride (SiB), and silicon boron nitride (SiBN).

6. The processing method of claim 1, wherein the superlattice structure is adjacent to the source/drain recess on the substrate, the superlattice structure having a plurality of first layers and corresponding plurality of second layers alternatingly arranged in a plurality of stacked pairs extending between the source/drain recess on the substrate.

7. The processing method of claim 1, wherein selectively depositing the silicon-containing dielectric layer comprises deposition at a temperature less than 500° C.

8. The processing method of claim 1, wherein the silicon-containing dielectric layer has a wet etch rate of less than 1 Å/min.

9. The processing method of claim 1, wherein densifying the silicon-containing dielectric layer comprises exposing the silicon-containing dielectric layer to a rapid thermal processing (RTP) process.

10. The processing method of claim 1, wherein densifying the silicon-containing dielectric layer comprises exposing the silicon-containing dielectric layer to a high-density plasma at a temperature less than or equal to 500° C. and at a pressure less than 1 Torr, the high-density plasma selected from one or more of nitrogen (N), helium (He), hydrogen (H₂), neon (Ne), argon (Ar), krypton (Kr), and xenon (Xe).

11. The processing method of claim 1, wherein the silicon-containing dielectric layer has a thickness in a range of from greater than 0 Å to 200 Å.

12. The processing method of claim 1, further comprising pre-cleaning a surface of the oxide liner within the source/drain recess on the substrate prior to selectively depositing the silicon-containing dielectric layer.

13. A processing tool comprising:
a central transfer station comprising a robot configured to move a wafer;
a plurality of process stations, each process station connected to the central transfer station and providing a processing region separated from processing regions of adjacent process stations, the plurality of process stations comprising one or more of a pre-cleaning chamber, an inhibitor soaking chamber, a selective deposition chamber, and a densification chamber; and
a controller connected to the central transfer station and the plurality of process stations, the controller configured to activate the robot to move the wafer between process stations, and to cause the processing tool to perform the operations of:
selectively deposit a silicon-containing dielectric layer in a source/drain recess on a substrate and through an opening in an oxide liner within the source drain recess; and
densify the silicon-containing dielectric layer.

14. The processing tool of claim 13, wherein the controller is configured to cause the processing tool for perform one or more of the further operations of:
prior to selectively depositing the silicon-containing dielectric layer:
pre-cleaning a surface of the oxide liner within the source/drain recess on the substrate; and
exposing the oxide liner to a growth inhibitor.

15. A method of forming a gate-all-around device, the method comprising:
forming an oxide liner on a sidewall surface of a superlattice structure and on a bottom surface of a source/drain recess adjacent to the superlattice structure on a substrate, the superlattice structure comprising a plurality of first layers and a corresponding plurality of second layers alternatingly arranged in a plurality of stacked pairs extending between the source/drain recess;
removing a portion of the oxide liner from the bottom surface of the source/drain recess;
selectively depositing a silicon-containing dielectric layer in the source/drain recess and through an opening in the oxide liner within the source drain recess; and
densifying the silicon-containing dielectric layer.

16. The method of claim 15, further comprising, prior to selectively depositing the silicon-containing dielectric layer, one or more of pre-cleaning a sidewall surface of the oxide liner and exposing the oxide liner to a growth inhibitor.

17. The method of claim 15, wherein densifying the silicon-containing dielectric layer forms a densified silicon-containing dielectric layer having a density gradient.

18. The method of claim 15, wherein selectively depositing the silicon-containing dielectric layer comprises deposition at a temperature less than 500° C.

19. The method of claim 15, wherein densifying the silicon-containing dielectric layer comprises exposing the silicon-containing dielectric layer to a rapid thermal processing (RTP) process.

20. The method of claim 15, wherein densifying the silicon-containing dielectric layer comprises exposing the silicon-containing dielectric layer to a high-density plasma at a temperature less than or equal to 500° C. and at a pressure less than 1 Torr, the high-density plasma selected from one or more of nitrogen (N), helium (He), hydrogen (H₂), neon (Ne), argon (Ar), krypton (Kr), and xenon (Xe).
